(19) United States
(12) Patent Application Publication
(10) Pub. No.: US 2009/0311865 A1
(43) Pub. Date: Dec. 17, 2009

(54) Method for double patterning lithography

(75) Inventor: Chen Kun Wang, Tainan City (TW)

Correspondence Address: BLISS MCGLYNN, P.C., 2075 WEST BIG BEAVER ROAD, SUITE 600, TROY, MI, 48084, US

(73) Assignee: Chung-Shan Ho

(21) Appl. No.: 12/456,316

(22) Filed: Jun. 15, 2009

(30) Foreign Application Priority Data
Jun. 17, 2008 (TW) 097122533
Mar. 25, 2009 (TW) 098109725

(51) Int. Cl. H01L 21/308

(52) U.S. Cl. 438/694; 438/689; 257/E21.231

(57) ABSTRACT

A method for double patterning lithography includes: (a) forming a first pattern on a first material layer that is formed on a semiconductor substrate, the first pattern having a plurality of first parts extending in a first direction and spaced apart along a second direction transverse to the first direction, and a plurality of first gaps among the first parts; (b) forming a second pattern on the first pattern, the second pattern having a plurality of second parts extending in the second direction and spaced apart along the first direction, and a plurality of second gaps among the second parts, the first and second gaps intersecting each other and cooperatively defining a plurality of uncovering regions where the first and second gaps intersect each other; and (c) etching portions of the first material layer exposed via the uncovering regions.

### CROSS-REFERENCE TO RELATED APPLICATION

This application claims priority of Taiwanese application no. 097122533, filed on Jun. 17, 2008, and also claims priority of Taiwanese application no. 098109725, filed on Mar. 25, 2009.

### BACKGROUND OF THE INVENTION

1. Field of the Invention

This invention relates to a method for photolithography, more particularly to a method for double patterning lithography in semiconductor microfabrication.

2. Description of the Related Art

Double patterning lithography is one of the most advanced lithography technologies in the semiconductor industry. In the field of semiconductors, a critical dimension (CD) of a semiconductor device is the width of features on the device. A pitch is generally defined as the critical dimension plus the distance to the next feature.

Referring to FIG. 1, a dielectric layer 11 of a semiconductor chip 1 is shown to include a plurality of trenches 12, 13, all of which are spaced apart from each other at equal distances (d1=d2). The formation of the trenches 12, 13 in semiconductor scale is preferably conducted by a double patterning lithography for forming the trenches 12 and the trenches 13 separately when the pitch of the features on the semiconductor chip 1 is not larger than 140 nm.

In detail, the conventional method for double patterning lithography is conducted as follows. Firstly, the dielectric layer 11 of the semiconductor chip 1 is prepared, and a first resist pattern (not shown) is formed on the dielectric layer 11 by a first photolithography process. The dielectric layer 11 on regions not covered by the first resist pattern is etched to form a plurality of trenches 12, followed by removing the first resist pattern. Then, a second resist pattern (not shown) is formed on the dielectric layer 11 with the trenches 12 thereon by a second photolithography process. The dielectric layer 11 on regions not covered by the second resist pattern is etched to form a plurality of trenches 13, followed by removing the second resist pattern. By the above steps, the semiconductor chip 1 with the trenches 12, 13 spaced apart by the predetermined distance are formed.

However, in practice, different runs of light exposure can produce variation of the widths or critical dimensions (CD) of the trenches 12, 13. Referring to FIG. 2, the distance of the trenches 12 from the trenches 13 can also vary (see d1′, d2′) due to an overlay error (alignment error) that occurs during alignment of photomasks for the first and second photolithography processes. Thus, it is difficult to provide a uniform distance between the trenches 12 and 13, especially when the critical dimensions thereof need to be shrunk.

Moreover, since forming of the trenches 12 and forming of the trenches 13 are conducted separately using respective single-lithography processes, and since each of the first and second resist patterns is photolithographed to have features not larger than 140 nm, either in width or in length directions, the photolithography resolution of the first and second resist patterns is limited so that the trenches 12, 13 are likely to have deformed corners, for example, round corners.

Furthermore, the overlay error that results in variation of the distance between the trenches 12 and 13 could decrease yield rate in subsequent processes. Because shrinkage of the critical dimension (CD) contributes much influence on an overlay process, the method for double patterning lithography for the trenches 12, 13 will become more and more sensitive to the overlay error when the pitch (i.e., the critical dimension (CD) of the trenches 12, 13 plus the space therebetween) of the semiconductor chip 1 is reduced further and further below 140 nm.

### SUMMARY OF THE INVENTION

An object of the present invention is to provide a method for double patterning lithography with an improved function of critical dimension shrinkage and with a wider tolerance range of overlay error (alignment error).

Accordingly, the method for double patterning lithography of the present invention comprises: (a) forming a first pattern on a first material layer that is formed on a semiconductor substrate, the first pattern having a plurality of first parts extending in a first direction and spaced apart along a second direction transverse to the first direction, and a plurality of first gaps among the first parts; (b) forming a second pattern on the first pattern, the second pattern having a plurality of second parts extending in the second direction and spaced apart along the first direction, and a plurality of second gaps among the second parts, the first and second gaps intersecting each other and cooperatively defining a plurality of uncovering regions where the first and second gaps intersect each other; and (c) etching portions of the first material layer exposed via the uncovering regions.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a schematic view to illustrate trenches of a semiconductor chip formed by a conventional method for double patterning lithography;

FIG. 2 is a schematic view to illustrate variation of the distance between adjacent trenches of FIG. 1 resulting from an overlay error;

FIG. 3 is a flow chart showing a method of double patterning lithography according to the present invention;

FIG. 4 is a schematic sectional view of the first embodiment illustrating that, after step 101, a first pattern is formed on a first material layer of a semiconductor chip according to the present invention;

FIG. 5 is a schematic sectional view of the first embodiment illustrating that, after step 102, a second pattern is formed on the first pattern shown in FIG. 4;

FIG. 6 is a schematic sectional view of the first embodiment illustrating that, after step 103, a plurality of trenches are formed in the first material layer;

FIG. 7 is a schematic top sectional view illustrating possible modes for adjusting an uncovering region formed at an intersection of the first and second patterns;

FIG. 8 is a schematic sectional view of the semiconductor chip formed after the first and second patterns shown in FIG. 6 are removed;

FIG. 9 is a schematic sectional view illustrating that, in the second embodiment of the present invention, the first pattern is formed on a protection layer which in turn is formed on the first material layer shown in FIG. 4; and

FIG. 10 is a schematic sectional view of the semiconductor chip formed according to the second embodiment of the present invention after the first and second patterns are removed.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

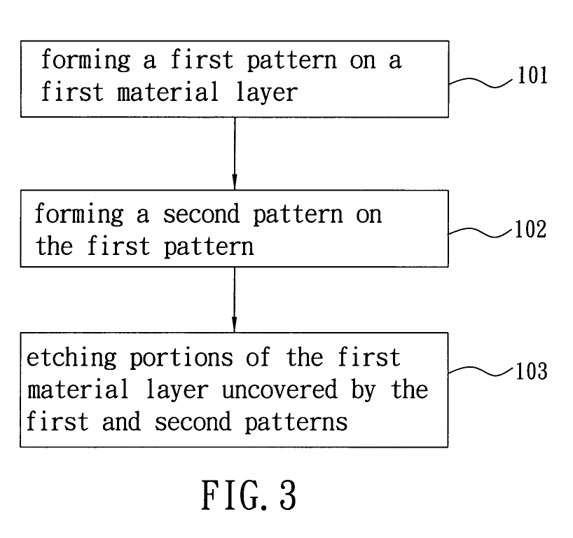

FIGS. 3 to 6 and 8 illustrate consecutive steps of a method for double patterning lithography according to the first embodiment of this invention to produce a semiconductor chip 2. The method includes: step 101 of forming a first pattern 3 on a first material layer 21, step 102 of forming a second pattern 4 on the first pattern 3, and step 103 of etching portions of the first material layer 21 uncovered by the first and second patterns 3, 4.

In step 101, the first material layer 21 is formed on a semiconductor substrate 20, and the first pattern 3 is formed on the first material layer 21.

The first material layer 21 is made of a dielectric material, such as silicon dioxide, silicon nitride, silicon oxide, SiC, SiON, TiN, or any other suitable material. The first material layer 21 can be formed by any well-known method, and thus, the description concerning the known methods is omitted herein.

The first pattern 3 is a hardmask, and is also made of the dielectric material, such as silicon dioxide, silicon nitride, silicon oxide, SiC, SiON, TiN, or any other suitable material. Any suitable materials may be selected for the first material layer 21 and the first pattern 3 as long as they have different etching rates so that etching depth and position can be controlled. Generally, the selection of the materials is determined by whether or not the materials can be obtained and processed easily.

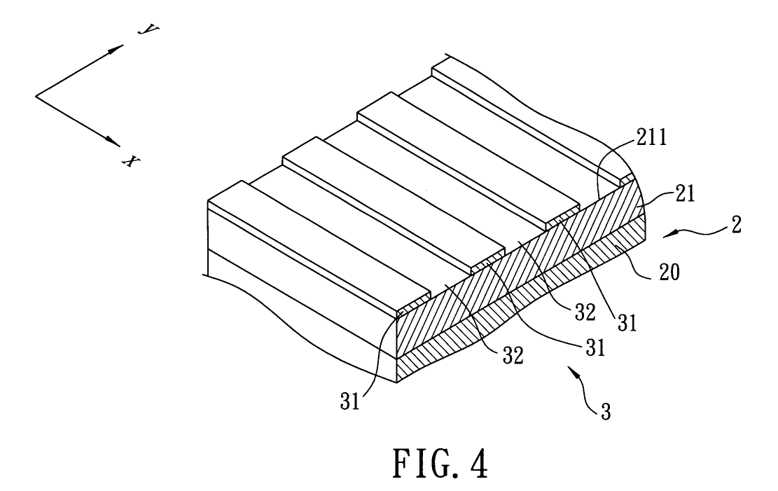

As shown in FIG. 4, the first pattern 3 has a plurality of first parts 31 extending in a first direction (x-direction) and spaced apart along a second direction (y-direction) transverse to the first direction (x-direction), and a plurality of first gaps 32 formed among the first parts 31.

In the first embodiment, the first pattern 3 is formed as follows. First, a second material layer (not shown) made of silicon nitride is formed on the first material layer 21, which is made of silicon oxide, by chemical vapor deposition and has a thickness of 1000 Å. Then, a photoresist layer (not shown) is applied to the second material layer. After a photolithography process using a first photomask (not shown), the photoresist layer is patterned to have a pattern corresponding to the first pattern 3 (FIG. 4). Thereafter, portions of the second material layer uncovered by the photoresist layer are etched, and the photoresist layer is removed from the second material layer, thereby forming the second material layer (silicon nitride) into the first pattern 3.

In step 102, the second pattern 4 is formed on the first pattern 3.

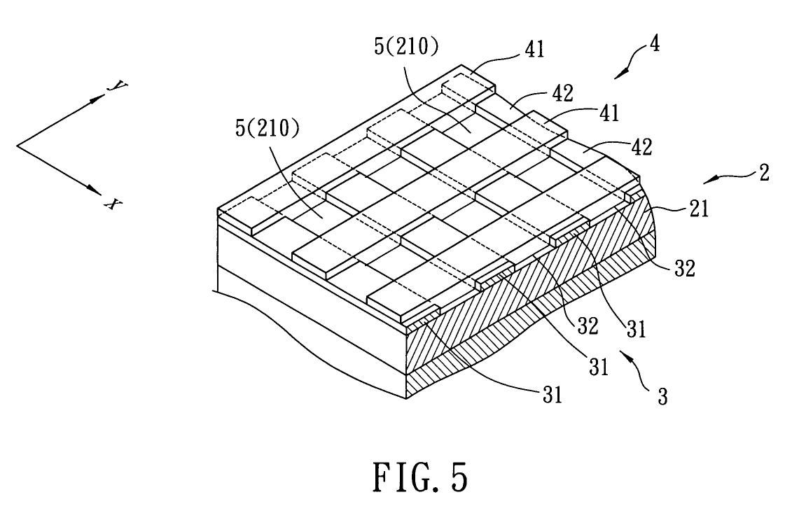

As shown in FIG. 5, the second pattern 4 has a plurality of second parts 41 extending in the second direction (y-direction) and spaced apart along the first direction (x-direction), and a plurality of second gaps 42 formed among the second parts 41. The first and second gaps 32, 42 intersect each other on the first material layer 21 and corporately define a plurality of uncovering regions 5 where they intersect. The second pattern 4 is made of a photoresist material that is either a positive-type or negative type.

In the first embodiment, the second pattern 4 is formed by coating a third material layer (not shown) made of a positive type photoresist material on the first pattern 3, followed by a photolithography process using another photomask (not shown). As a result, the third material layer is patterned to form the second pattern 4.

Particularly, the first and second parts 31, 41 are in the form of straight lines, and the uncovering regions 5 are four-sided grooves that are formed where the first and second gaps 32, 42 intersect each other.

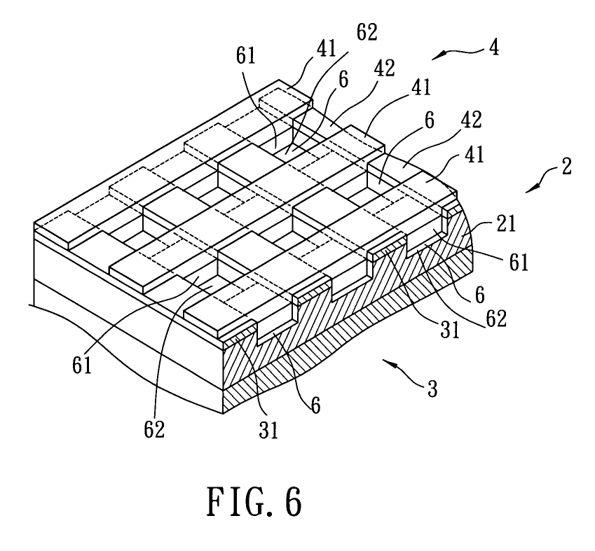

In step 103, portions 210 (FIG. 5) of the first material layer 21 exposed via the uncovering regions 5 are etched so that a plurality of trenches 6 are formed in the first material layer 21 (FIG. 6). Each of the trenches 6 has four sidewalls 61 and a bottom surface 62.

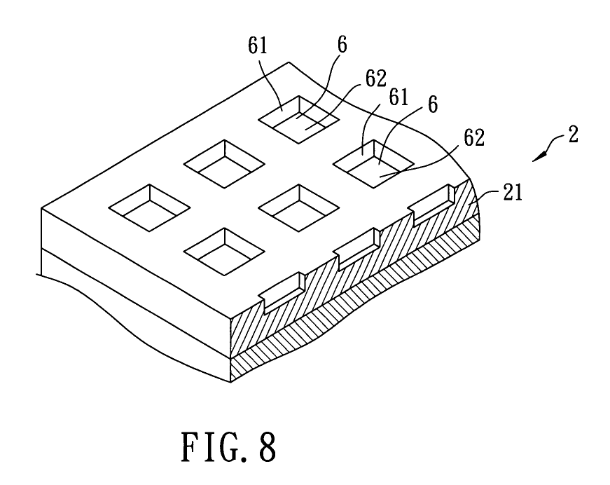

After step 103, the second pattern 4 and the first pattern 3 are removed in sequence by using one of plasma, etching, and chemical mechanical polishing. After removing the first and second patterns 3, 4, the semiconductor chip 2 shown in FIG. 8 is formed.

It should be noted that the pitch of the first and second patterns 3, 4 is not larger than 140 nm and is defined as the width of the first or second parts 31, 41 plus the width of the first or second gaps 32, 42. When the pitches of the first and second patterns are larger than 140 nm, it is not necessary to use the method for double patterning lithography according to the present invention.

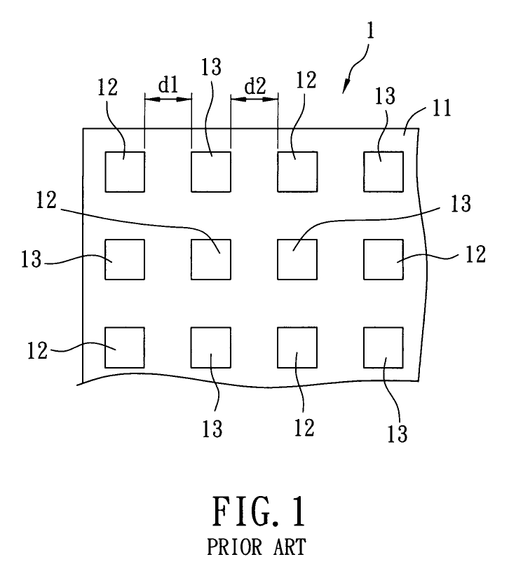

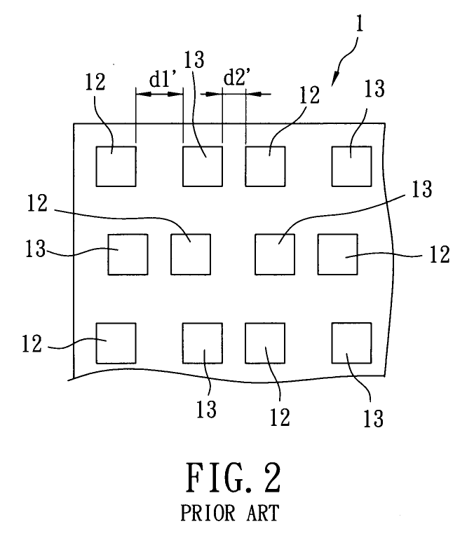

Since the trenches 6 are formed at intersection points of the first and second gaps 32, 42 by combining two lithography processes, and since the first and second parts 31, 41 are formed as lines which are sized to be smaller than 140 nm only in their width directions (i.e. one of the x-direction or y-direction), the first and second patterns 3, 4 can be provided with a photolithography resolution higher than that of the resist patterns used in the prior art (see FIGS. 1 and 2) and having trench dimensions smaller than 140 nm in both x-direction and y-direction. Accordingly, the method of the present invention has an improved CD shrinkage function. In addition, the shape of the trenches 6 is less irregular than that of the trenches 12, 13 formed in the prior art, and each trench 6 can have right angles at four corners formed by the top edges of the four sidewalls 51.

On the other hand, when the first pattern 3 or the second pattern 4 displaces from its pre-designed position in case of an overlay error, all of the uncovering regions 5 will shift in the same direction (x-or y-direction) and by the same distance. Therefore, the dimension of the uncovering regions 5 will not deviate from the pre-designed dimension, thereby eliminating the problem of dimensional variation encountered by the trenches 12, 13 of the prior art as shown in FIG. 2.

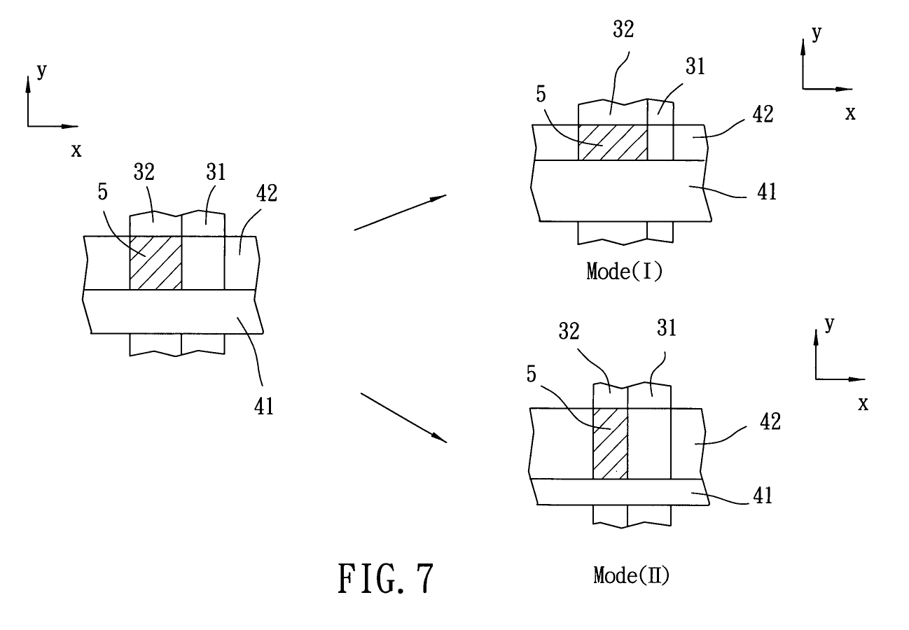

Referring to FIG. 7, the method of the present invention permits an adjustment for each uncovering region 5 without changing the area thereof (i.e., an intersection area of the first and second gaps 32, 42). When the dimension of the uncovering region 5 is increased in the X-direction, the dimension thereof in the Y-direction can be decreased for area adjustment so that the pre-designed area thereof can be maintained (see mode I). When the dimension of the uncovering region 5 is decreased in the X-direction, the dimension thereof in the Y-direction can be increased for area adjustment so that the pre-designed area thereof can be maintained (see mode II). The adjustment can improve overlay process window.

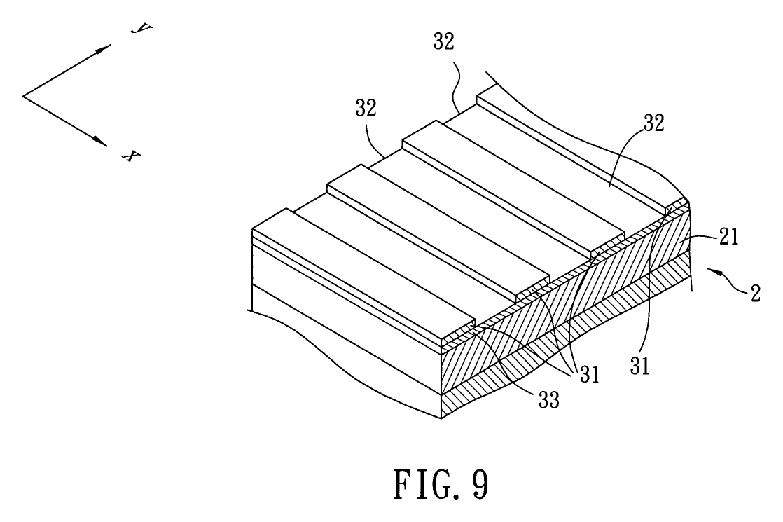

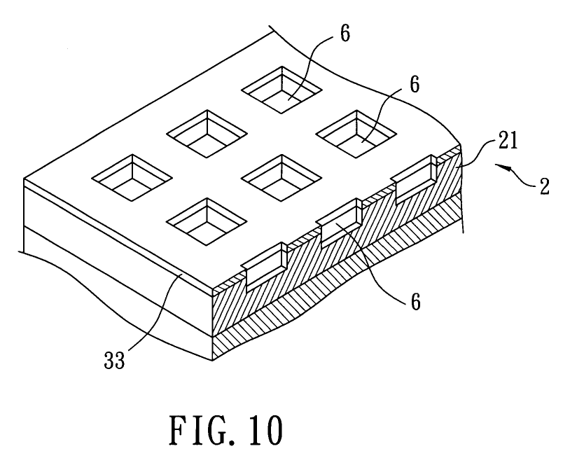

Referring to FIGS. 9 and 10, the semiconductor chip 2 is provided with a protection layer 33 on the first material layer 21 according to the second preferred embodiment of the present invention. The second embodiment differs from the previous embodiment in that the protection layer 33 is formed between the first pattern 3 and the first material layer 21, and is exposed from the first gaps 32, after step 101 (see FIG. 9). The protection layer 33, the first pattern 3, and the first material layer 21 have different etching rates such that etching depth and position can be adjusted.

Furthermore, the protection layer 33 can be made of any suitable materials used in semiconductor processing. In the second embodiment, the protection layer 33 is made of silicon nitride and is formed on the first material layer 21, which is made of silicon oxide, by chemical vapor deposition and has a thickness of 1000 Å. The first pattern 3 is made of silicon dioxide and has a thickness of 1000 Å. In step 103, the protection layer 33 at the uncovering regions 5 is etched together with the first material layer 21. After the first and second patterns 3, 4 are removed, the semiconductor chip 2 has a configuration shown in FIG. 10.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A method for double patterning lithography, comprising:
(a) forming a first pattern on a first material layer that is formed on a semiconductor substrate, the first pattern having a plurality of first parts extending in a first direction and spaced apart along a second direction transverse to the first direction, and a plurality of first gaps among the first parts;
(b) forming a second pattern on the first pattern, the second pattern having a plurality of second parts extending in the second direction and spaced apart along the first direction, and a plurality of second gaps among the second parts, the first and second gaps intersecting each other and cooperatively defining a plurality of uncovering regions where the first and second gaps intersect each other; and
(c) etching portions of the first material layer exposed via the uncovering regions.

2. The method of claim 1, further comprising: (d) removing the second pattern after step (c).

3. The method of claim 2, further comprising: (e) removing the first pattern after step (d).

4. The method of claim 1, wherein each of the first and second parts is in the form of a straight line.

5. The method of claim 1, further comprising forming a protection layer between the first pattern and the first material layer, the protection layer being etched together with the first material layer in step (c), wherein the protection layer, the first parts, and the first material layer have different etching rates.

6. The method of claim 4, wherein, after step (c), a plurality of trenches are formed in the first material layer, each of the trenches being confined by four sidewalls.

7. The method of claim 4, wherein the first pattern has a pitch which is not larger than 140 nm.

8. The method of claim 4, wherein the second pattern has a pitch which is not larger than 140 nm.

9. The method of claim 1, wherein the first pattern has a different etching rate relative to the first material layer.

10. The method of claim 1, wherein the second pattern is made of a photoresist material.

11. The method of claim 1, wherein the first pattern is a hardmask.
